(19) United States
(12) Patent Application Publication
(10) Pub. No.: US 2024/0201583 A1
(43) Pub. Date: Jun. 20, 2024

(54) PHYSICALLY DETECTABLE ID INTRODUCED BY LITHOGRAPHY SRAF INSERTION FOR HETEROGENEOUS INTEGRATION

(71) Applicant: International Business Machines Corporation, Armonk, NY (US)

(72) Inventors: Cheng Chi, Jersey City, NJ (US); Takashi Ando, Eastchester, NY (US); Praneet Adusumilli, Somerset, NJ (US); Reinaldo Vega, Mahopac, NY (US); David Wolpert, Poughkeepsie, NY (US)

(21) Appl. No.: 18/083,851

(22) Filed: Dec. 19, 2022

(51) Int. Cl. G03F 7/00; G03F 7/09; G03F 7/20; G06K 19/06

(52) U.S. Cl. CPC G03F 7/0005; G03F 7/09; G03F 7/2047; G03F 7/70325; G06K 19/06028; G06K 19/06037

(57) ABSTRACT

A system and method of leveraging sub-resolution assist feature (SRAF) to intentionally distort a feature of a pattern for identification and security purposes. A method of forming an identifier on a semiconductor structure includes: receiving, at a semiconductor manufacturing foundry, a specification of an identifier including a pattern comprising a combination of main features; designing a lithographic mask structure based on the received identifier specification, the lithographic mask structure including mask features corresponding to the specified main features and at least one sub-resolution assist feature (SRAF) structure in a geometrical relationship with a corresponding mask feature for forming, using a lithography process, a uniquely modified identifier pattern comprising a combination of modified main features; and then subsequently lithographically exposing, employing the mask structure, photoresist layers at an optical condition and subsequently developing the photoresist layers to transfer the uniquely modified identifier pattern to a surface of a semiconductor wafer.

### FIELD

The present disclosure relates to a method of fabricating an identifier (ID) in a semiconductor structure using a sub-resolution assist feature (SRAF).

### BACKGROUND

In semiconductor fabrication plants, photolithography is used to form masks that are used to transfer patterns into semiconductor surfaces and structures. Sub-resolution assist features (SRAFs) are commonly used in lithography masks to improve the printability and process window of critical features. SRAFs are typically added to mask shapes to create a denser environment for a more robust printing of main features. Typically, the SRAFs are not intended to be reproduced as distinct features in the photoresist, but they influence and modify the exact shape with which the main features are printed in the photoresist in the presence of the SRAFs relative to shapes that would be printed in the absence of the SRAFs. In order to avoid direct printing of the SRAFs, the size and location of the SRAFs are carefully optimized. If properly optimized, the SRAFs can provide benefit to the process performance of the lithographic process, for example, by increasing the depth of focus or process window, while avoiding direct printing of the SRAFs as separate but unintended patterns that could transfer to subsequent steps of the chip manufacturing process.

Conventionally, SRAFs are placed as part of an overall data preparation program that includes a model based optical proximity correction (OPC) algorithm for all incoming design patterns that are placed on a lithographic mask.

An accurate SRAF model is supposed to correctly predict the effects that the SRAFs have on the main feature(s) including any shift in the best focus, and any undesirable printing of direct images of the SRAFs at the top, or the bottom, of the photoresist.

### SUMMARY

In an aspect of the present disclosure there is provided a system and method of producing a physically detectable identifier (ID) introduced by lithography SRAF insertion for a semiconductor structure or assembly.

In an aspect, SRAFs employed on photolithographic masks for use when printing features are being leveraged to intentionally distort a feature for security purposes.

In an aspect, both a customer and a foundry contribute to the generation of the physically detectable identifier.

In an aspect, the identifier can be a one-dimensional barcode-like structure or a two-dimensional QR-code-like structure formed in an area of a semiconductor substrate or wafer.

According to an aspect of the present disclosure, there is provided a method of forming an identifier on a semiconductor structure. The method comprises: receiving, at a semiconductor manufacturing foundry, a specification of an identifier including a pattern comprising a combination of main features; designing a lithographic mask structure based on the received identifier specification, the lithographic mask structure including mask features corresponding to the specified main features and at least one sub-resolution assist feature (SRAF) structure in a geometrical relationship with a corresponding mask feature for forming, using a lithography process, a uniquely modified identifier pattern comprising a combination of modified main features; and subsequently lithographically exposing, employing the mask structure, photoresist layers at an optical condition and subsequently developing the photoresist layers to transfer the uniquely modified identifier pattern to a surface of a semiconductor wafer.

According to a further aspect, there is provided an identification structure for a semiconductor chip. The identification structure comprises: a plurality of adjacent patterns with variable size and spacing on a semiconductor chip to form a unique identifier pattern.

Further to this aspect, the plurality of adjacent patterns is based upon: an initial identifier pattern comprising a combination of main features specified by a first entity; and a lithographic mask structure designed by a second entity, the lithographic mask structure including mask features corresponding to the specified main features and at least one sub-resolution assist feature (SRAF) structure in a geometrical relationship with a corresponding mask feature for forming, using a lithography process, the unique identifier pattern.

### BRIEF DESCRIPTION OF THE DRAWINGS

FIG. 1 is a schematic diagram illustrating a set of steps that can be employed using an optics system and a lithographic material stack to implement an embodiment of the present disclosure;

FIG. 2 depicts a process flow to integrate an identifier (ID) code into a Heterogeneous Integration (HI) assembly or package such as an IC chip substrate of a semiconductor wafer according to an embodiment of the present disclosure;

FIG. 3 is an illustrative example of fabricating an exemplary one-dimensional ID bar code including the use of additional SRAF features in the form of additional lines provided at select locations in a mask that will result in altering the original ID code features submitted by a customer; and

FIGS. 4A-4D depicts an example simulation showing an initial customer-provided design within the foundry's groundrules and the types of resulting final bar-code design variations in an ID area that can result from different placements of SRAF of the mask used to produce the final design at the foundry.

### DETAILED DESCRIPTION

As stated above, the present disclosure relates to a method of producing a physically detectable identifier (ID) introduced by lithography SRAF insertion, which is now described in detail with accompanying figures. Like and corresponding elements mentioned herein and illustrated in the drawings are referred to by like reference numerals. The drawings are not necessarily drawn to scale.

Photolithographic masks are used to fabricate semiconductor devices such as integrated circuits. The masks are patterned according to the images that are to be printed on, e.g., a silicon wafer. Light is transmitted through the openings in the mask and focused onto a photoresist layer that has been coated on the silicon wafer. The transmitted and focused light exposes portions of the photoresist. A developer is used to remove either the exposed portions or the unexposed portions of the resist layer, depending upon whether the photoresist is a positive or negative type resist. The remaining photoresist serves to preotext the underlying layer during further processing of the wafer (e.g., etching exposed portions of the underlying layer, implanting ions in the wafer, etc.).

As used herein, Heterogeneous Integration (HI) refers to the integration of separately manufactured components into a higher level assembly (System-in-Package) that, in the aggregate, provides enhanced functionality and improved operating characteristics. The combined components can vary in system level (e.g., pre-assembled package or subsystem), functionality (e.g., specialized processors, DRAM, flash memory, surface mount device (SMD), resistor/capacitor/inductor, filters, connectors, MEMS device, sensors) and technologies (e.g., one optimized for die size with another one optimized for low power). The overall idea behind heterogeneous integration is to integrate multiple dies in the same package. This enables the package to perform a specific and advanced function in a small form factor.

As used herein, a “main feature” refers to a portion of the mask pattern that is intended for printing in a photoresist layer, i.e., intended for lithographically exposing the photoresist material on a wafer with sufficient illumination intensity to react with the photo-sensitive photoresist material. In the case of a photoresist layer including a positive photoresist material, the lithographically exposed portions of the photoresist layer become soluble to the developer solution and are removed when the developer is applied. A main feature is a resolvable feature that causes incident radiation to illuminate the photoresist with enough intensity so that the resolvable feature is developed away through the entire or nearly the entire thickness of the photoresist.

As used herein, a “sub-resolution assist feature (SRAF)” refers to a portion of the mask pattern that is intended to enhance the printing of a main feature without producing a physically manifested pattern in a photoresist layer that is printed as a result of the presence of the SRAF alone. The robustness of the main feature printing performance when affected by process variations such as focus or dose is enhanced by SRAFs. However, the intensity of the image of the SRAFS at the wafer plane is kept below the threshold for inducing a chemical reaction in the photoresist. Ideally, an image of an SRAF should not be present in an exposed photoresist layer in order to avoid impacting subsequent steps such as etch and deposition, and ultimately causing the manufactured chip to fail.

A design layout can be transferred from a lithographic mask to a photoresist layer coated on a substrate (i.e., a wafer) by etching design shapes on the lithographic mask, illuminating the lithographic mask with a radiation, and focusing the diffraction from the lithographic mask onto the photoresist layer via a system of lenses. To enhance resolution and robustness to focus deviations of the image intensity distribution on the photoresist layer, SRAFs are added to the lithographic mask as additional features or shapes. The SRAFs are not intended to be resolved in the photoresist layer. Shape and placement of the SRAFs must be optimized to provide the maximum benefit without resolving on the photoresist layer. Ideally, an SRAF should not even marginally resolve in the form of small indentations on the surface of the photoresist layer because even such small indentations could be transferred into the substrate in subsequent etch processes that employ the patterned photoresist layer as an etch mask.

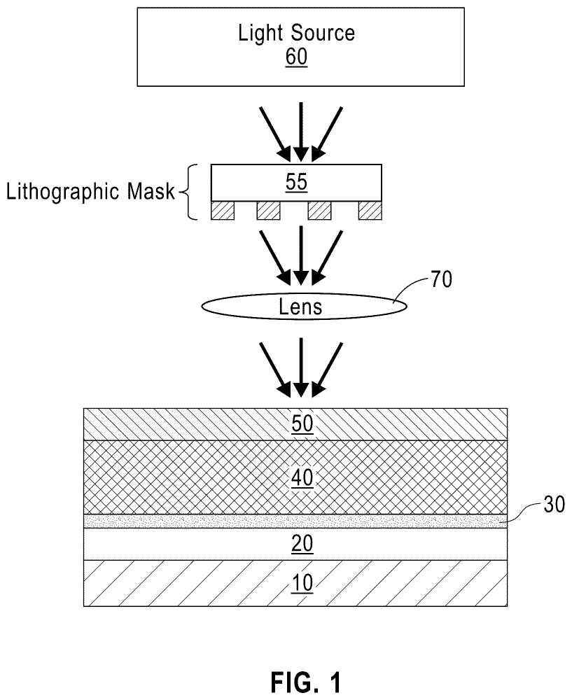

FIG. 1 illustrates an optics system and a lithographic material stack. The lithographic material stack includes, from bottom to top, a substrate 10, an underlayer 20 that is subsequently deposited on the substrate 10 and including at least one of a semiconductor material, a conductive material, and an insulator material, a bottom antireflective coating (BARC) layer 30, a photoresist layer 40, and a top antireflective coating (TARC) layer 50. A lithographic mask 55 includes physical shapes corresponding to the design to be transferred to the photoresist layer 40 on the substrate 10, which can be a wafer as known in the art. The illumination conditions include, among others, polarization of the illumination beam, a source mask pattern, and the optics of the lens system.

A lithographically exposed photoresist layer 40 is subsequently developed. Depending on the polarity of the material of the photoresist layer 40, lithographically exposed portions or unexposed portions of the photoresist layer 40 are removed during the development step, thereby generating a developed photoresist layer with topography. The developed photoresist layer 40 is the patterned photoresist layer, from which images of the patterned photoresist layer can be subsequently generated. The images of the patterned photoresist layer can be generated, for example, employing a scanning electron microscopy (SEM) apparatus.

In the system of FIG. 1, a design layout can be transferred from the lithographic mask 55 to a photoresist layer coated on a substrate (i.e., a wafer) by etching design shapes on the lithographic mask 55, illuminating the lithographic mask with a radiation from a light source 60, and focusing the diffraction from the lithographic mask onto the photoresist layer via a system of lenses 70. To enhance resolution and robustness to focus deviations of the image intensity distribution on the photoresist layer, SRAFs are added to the lithographic mask as additional features or shapes. The SRAFs are not intended to be resolved in the photoresist layer. Shape and placement of the SRAFs however, are optimized to provide the maximum benefit without resolving on the photoresist layer. Ideally, the SRAF should not even marginally resolve in the form of small indentations on the surface of the photoresist layer because even such small indentations could be transferred into the substrate in subsequent etch processes that employ the patterned photoresist layer as an etch mask.

It is the case that security is critical to the heterogeneous integration which refers to the integration of separately manufactured components into a higher level assembly that, in the aggregate, provides enhanced functionality and improved operating characteristics. During the HI package, it is the case that conventional ID code-like features are either provided by one of the foundry or by the customers which eventually is manufactured into the assembly. It is the case that this process is not secure enough. Moreover, conventional ID code also does not correlate with the process change or any impact from time and space.

In embodiments herein, an HI approach requires both foundry (where the silicon wafer is fabricated) and customer provided input for ID area. For example, the customer can provide first information e.g., an initial design of features (e.g., a public key) and then the foundry provides another level of control for creating the mask, i.e., provide further features in the form of process controls (e.g., a private key) which take the form of a placement of SRAFs on the lithographic mask used to produce the ID code structure for the particular product. Thus, information from both foundry and customer is needed to unlock the final shape of the code-structure.

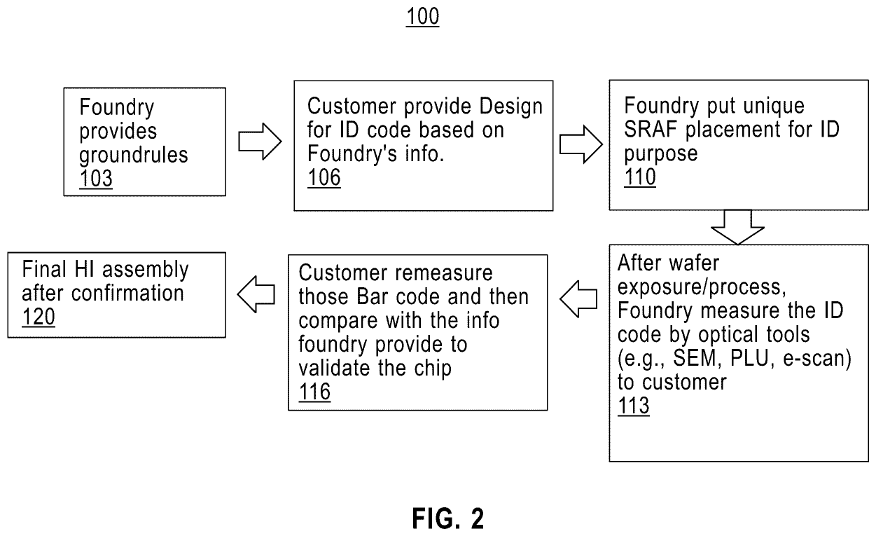

FIG. 2 shows a method 100 to integrate an identifier (ID) code into a HI assembly or package such as an IC chip substrate of a semiconductor wafer. A first step 103 involves the issuing of groundrules by the foundry. The groundrules define the minimum and maximum feature sizes (e.g., minimum line pitch dimension that can be printed, minimum feature line widths, shapes, distance between assistant features and main features, etc.) for identification codes to be printed into a final HI assembly, e.g., a substrate. Then, at 106, the foundry then receives from the customer, a design or pattern, e.g., of geometric shapes, for use as an ID code to be placed on the wafer or substrate in the HI assembly. The initial design provided by the customer for the ID code is based on the foundry's groundrules information.

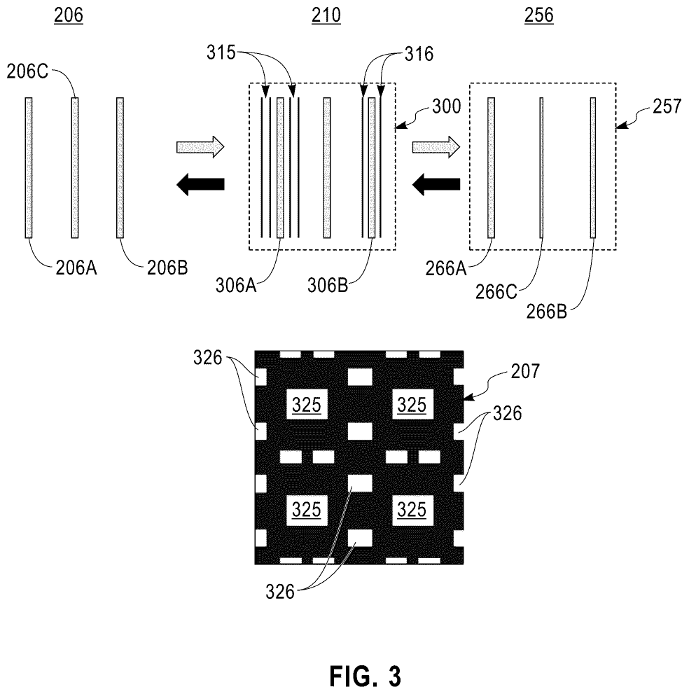

As shown in FIG. 3, one non-limiting design pattern for use as an ID code provided to the foundry by the customer is in the form of a one-dimensional bar code 206, e.g., a series of lines of uniform width and length, albeit each line feature and spacing between lines (i.e., pitch) within the limitations of features and dimensions specified by the foundry groundrules. The design provided by the customer can also be in the form of a two-dimensional code such as a Quick Response-code, e.g., QR-code 207, made up of black and white pixel patterns or area patterns.

Returning to FIG. 2, at 110, for the customer provided exemplary ID bar code, e.g., the one-dimensional bar code 206 shown in FIG. 3, the foundry generates a corresponding mask for use in a semiconductor optical lithographic system used to provide the ID feature on a wafer. During this step, according to an embodiment herein, at 110, the foundry puts unique SRAF placements in the semiconductor masks used to transfer the ID code pattern for purposes of manufacturing a unique ID code specified by the customer. In an embodiment, the foundry places the additional SRAF features in a geometrical relationship with corresponding main features into the mask to uniquely modify the ID code provided by the customer. For each main feature, multiple sets of at least one SRAF and/or multiple types of geometry between the main feature and the at least one SRAF can be provided.

As shown in FIG. 3, in an illustrative example, at step 210, for the exemplary ID bar code 206, additional SRAF features in the form of additional lines are provided at select locations in a mask 300 that will result in altering the original ID code features submitted by the customer. For example, in the mask 300, for a corresponding main feature line 306A formed in the pattern transferring mask 300 corresponding to the original line 206A of customer ID code 206, additional SRAF openings 315 of thinner width but of substantially equal length are formed on either side of this mask feature line which will have the effect of increasing the width of the original line 206A when the code pattern is transferred to a wafer using an optical lithographic process of FIG. 1. Similarly, in mask 300, for a corresponding main feature line 306B formed in the pattern transferring mask 300 corresponding to the original feature line 206B of customer-provided ID code 206, additional SRAF openings 316 of thinner width but of substantially equal length are formed on either side of this mask feature line which will have the effect of decreasing the width of the original main feature line 206B when the ID code pattern 206 is transferred to a wafer. In an embodiment, the foundry adheres to SRAF insertion rules which can dictate the minimum dimensions of the width of the inserted SRAF line, e.g., width of line 315, the minimum distance between the inserted SRAF line 315 and the mask feature line used to print the corresponding main feature line, e.g., line 206A, and the minimum distance between two adjacent inserted SRAF lines 315. Ideally, the shapes of the main feature lines 306A, 306B, etc. of pattern 206 are intended to be physically manifested in a developed photoresist, and the shapes of the SRAFs 315, 316 are intended not to be physically manifested in the developed photoresist—however are used to modify the shape of the main features 306A, 306B when the corresponding photoresist layer (not shown) is lithographically exposed and subsequently developed.

Similarly, for the case of the QR-code type pattern 207, shown in FIG. 3, an exemplary lithographic mask would include main features 325 and SRAFs 326. Ideally, the shapes of the main features 325 of pattern 207 are intended to be physically manifested in a developed photoresist, and the shapes of the SRAFs 326 are intended not to be physically manifested in the developed photoresist—however are used to modify the shape of the main features 325 when the corresponding photoresist layer (not shown) is lithographically exposed and subsequently developed.

Continuing the process, in view of FIG. 3, the mask 300 created at the foundry corresponding to the customer ID code with SRAF features added, is then subject to an optical lithographic process by being placed on a semiconductor wafer or substrate coated with a light sensitive polymer, e.g., a photoresist. This mask/photoresist structure is then exposed and developed to form a three-dimensional image 256 on the wafer, chip substrate, or any desired portion of the HI assembly. In embodiments, the photoresist image has the shape of the designed or intended customer bar-code pattern in the plane of the wafer subject to the variations engendered by the additional SRAF features. In the case of the example customer provided bar-code pattern 206, the final pattern 256 will have vertical walls through the thickness of the resist. Thus, the final resist pattern is binary: parts of the substrate are covered with resist while other parts are completely uncovered. This binary pattern is needed for pattern transfer since the parts of the substrate covered with resist will be protected from etching, ion implantation, or other pattern transfer mechanism.

In view of FIG. 3, the final pattern 256 on the wafer is thus determined by both customer design (customer input) and SRAF placement at foundry (foundry input) for ID generation and constitutes a detectable ID, i.e., a unique set of features or a fingerprint, in an ID area 257 that can be read by a physical inspection using e-beam, optical or electrical metrology tools. As shown in FIG. 3, the example final pattern transferred to the wafer corresponding to the initial customer bar code design 206 includes a detectable bar code final pattern 256 having different width of lines, e.g., a thicker line 266A corresponding to initial bar code line 206A, a thinner line 266B corresponding to initial bar code line 206B, that is reduced in thickness relative to thicker bar code line 266A, and an even thinner line 266C that is thinner than the initial corresponding bar code line 206C of the initial customer input.

In an embodiment, the pattern transfer can be spatially invariant—such that the SRAF is used as a foundry signature and is repeatable. In alternate embodiments, the pattern transfer can be temporally variant, i.e., the foundry uses different exposure/develop conditions to vary a feature as a function of time. With respect to these temporally variant transformations, the foundry may share some of this information with customer such as any of the unique exposure/develop conditions used when transferring the pattern to the wafer; otherwise, this information can be used by the foundry to track the “batch” of processed wafers.

Returning to FIG. 2, at 113, after wafer exposure/process, the foundry can measure the ID code final pattern 256 by optical tools (e.g. Scanning Electron Microscope, PLY (wafer defect inspection), e-scan) and provides the measurements of the final pattern 256 to the customer. Then, at 116, in order to validate the chip, the customer can re-measure those bar code features of the final pattern 256 and then compare the re-measurement values with the measurement information the foundry provided. Continuing, to 120, FIG. 2, after confirming the measurements to validate the chip ID code, the wafer may then be subject to a final HI assembly.

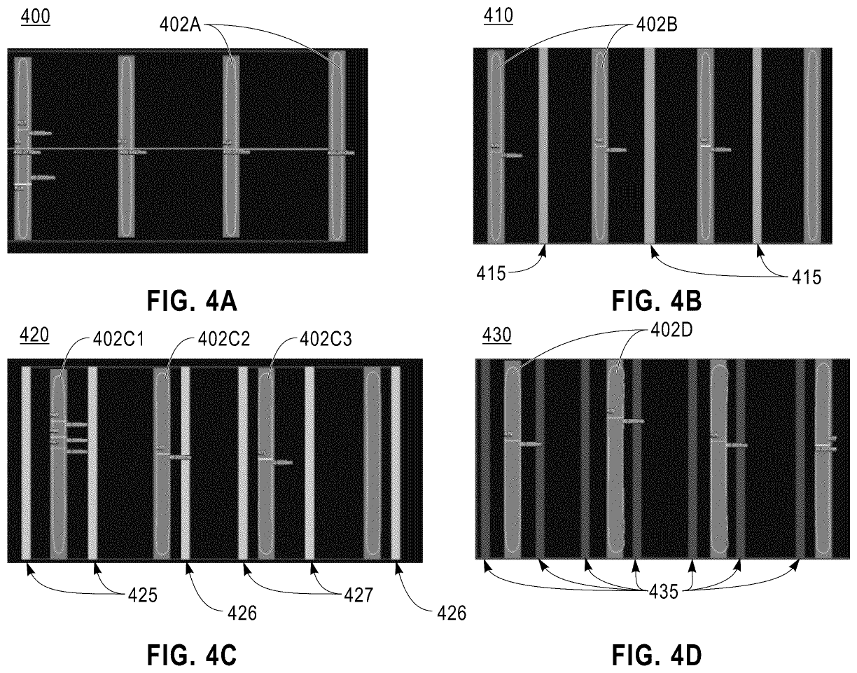

FIGS. 4A-4D shows a simulation depicting an initial customer-provided design within the foundry's groundrules and the types of resulting final bar-code design variations in an ID area that can result from different placements of SRAF of the mask used to produce the final design at the foundry. The customer-provided initial design shown in FIG. 4A, is in the form of a bar-code 400 including a series of parallel lines 402A, each line approximately 36 nm in width and each spaced apart at a pitch of about 400 nm.

FIG. 4B shows a first example mask 410 including a placement of sub resolution assist features inserted in the mask and the resulting lines 402B of final printed pattern of the final bar-code design. These inserted mask SRAF features include a pattern 415 of lines, each SRAF line structure formed equidistant between adjacent mask feature lines 402A used to print the corresponding original bar-code design specification and which provides a minimum variation such as a slight decrease in the width in the corresponding lines 402B of the resulting printed bar-code design.

FIG. 4C shows a second example mask 420 including a placement of sub resolution assist features inserted in the mask and the resulting lines 402C of final printed pattern of the final bar-code design. These inserted mask SRAF features include a two lines 425 placed approximately equidistant on either side of a first mask feature line 402A used to print the corresponding original bar-code design, a further SRAF feature line 426 formed close to a next adjacent first mask feature line 402A used to print the corresponding original bar-code design, a further SRAF feature line 427 formed close to a next adjacent first mask feature line 402A used to print the corresponding original bar-code design however located proximate the formed further SRAF feature line 426 within the spacing between original feature lines 402A, and a further SRAF feature line 427 formed on the other side of that next adjacent first mask feature line 402A however located a further distance away. There is also a similar further SRAF feature line 426 formed close to a next adjacent first mask feature lines 402A used to print the corresponding original bar-code design. It is seen that the placement of inserted SRAF lines 425, 426 and 427 in the mask used to print the original pattern of feature lines 402A in the manner as shown will result in a variation in the widths of the corresponding lines 402C of the resulting printed bar-code design. For example, the placement of inserted SRAF lines 425 will increase the transferred line 402C1 of the final pattern 420 to about 60 nm, while the placement of inserted SRAF lines 426 will increase the width of the transferred line 402C2 of the final pattern 420 to about 49 nm. Further, in the example, the placement of inserted SRAF lines 427 will increase the width of the transferred line 402C3 of the final pattern 420 to about 52 nm.

FIG. 4D shows a further example mask 430 including a placement of sub resolution assist features inserted in the mask and the resulting lines 402D of final printed pattern of the final bar-code design. These inserted mask SRAF features include a pattern 435 of lines, each SRAF line structure formed equidistant by a small distance on either side of adjacent mask feature lines 402A used to print the corresponding original bar-code design specification lines 402A which provides a minimum variation such as an increase in the width in each of the corresponding lines 402D of the resulting printed bar-code design to about 60 nm.

Thus, FIGS. 4A-4D illustrate that SRAF placement will lead to the significant variation of “bar code” width (e.g., from 35 nm to approximately 60 nm) and these resulting features can be further modified by further controlling or varying the SRAF feature width, or the number of SRAF features inserted.

According to embodiments herein, with SRAF insertion, the pattern shape on wafer is more reliable and stable than simply finding features in the process margins. Due to both SRAF and lithography capability from different foundries, this bar code will be a signature for a foundry and will be unique for a die.

While the disclosure has been described in terms of specific embodiments, it is evident in view of the foregoing description that numerous alternatives, modifications and variations will be apparent to those skilled in the art. Various embodiments of the present disclosure can be employed either alone or in combination with any other embodiment, unless expressly stated otherwise or otherwise clearly incompatible among one another. Accordingly, the disclosure is intended to encompass all such alternatives, modifications and variations which fall within the scope and spirit of the disclosure and the following claims.

What is claimed is:

1. A method of forming an identifier on a semiconductor structure, said method comprising:
receiving, at a semiconductor manufacturing foundry, a specification of an identifier including a pattern comprising a combination of main features;
designing a lithographic mask structure based on the received identifier specification, the lithographic mask structure including mask features corresponding to the specified main features and at least one sub-resolution assist feature (SRAF) structure in a geometrical relationship with a corresponding mask feature for forming, using a lithography process, a uniquely modified identifier pattern comprising a combination of modified main features; and
subsequently lithographically exposing, employing said mask structure, photoresist layers at an optical condition and subsequently developing said photoresist layers to transfer said uniquely modified identifier pattern to a surface of a semiconductor wafer.

2. The method according to claim 1, wherein said pattern comprises: a one-dimensional bar-code pattern wherein said main features are a series of spaced apart lines, each line of a same pre-determined width and uniform spacing between adjacent lines.

3. The method according to claim 1, wherein said pattern comprises: a two-dimensional QR-code pattern wherein said main features are a two-dimensional pattern of black and white areas.

4. The method according to claim 2, wherein said at least one SRAF is one or more lines interspersed throughout the series of spaced apart main feature lines.

5. The method according to claim 4, wherein the modified main features of said uniquely modified identifier pattern comprises one or more spaced apart lines of varying widths.

6. The method according to claim 4, wherein the modified main features of said uniquely modified identifier pattern comprises the spaced apart lines of non-uniform varying spacing between one or more adjacent lines.

7. The method according to claim 1, wherein said transfer of said uniquely modified identifier pattern to the surface of a semiconductor wafer is a spatially invariant transformation.

8. The method according to claim 1, wherein said transfer of said uniquely modified identifier pattern to the surface of a semiconductor wafer comprises temporally variant transformations of an optical exposure condition, a photoresist layer development condition, or both an optical exposure condition and photoresist layer development condition to vary said uniquely modified identifier pattern as a function of time.

9. The method according to claim 1, wherein said semiconductor manufacturing foundry receives the specification of an identifier including the pattern from a customer, the specification specifying the combination of main features that meet a pre-determined manufacturing groundrules.

10. The method according to claim 9, wherein after said photoresist layer exposure at an optical condition and subsequently developing of said uniquely modified identifier pattern, the method further comprising:
measuring, using an optical tool, the uniquely modified identifier pattern; and
sending said measurements of the uniquely modified identifier pattern obtained by the optical tool to the customer for validating a semiconductor component including the uniquely modified identifier pattern.

11. An identification structure for a semiconductor chip, the identification structure comprising:
a plurality of adjacent patterns with variable size and spacing on a semiconductor chip to form a unique identifier pattern.

12. The identification structure of claim 11, wherein the plurality of adjacent patterns is based upon:
an initial identifier pattern comprising a combination of main features specified by a first entity;
a lithographic mask structure designed by a second entity, the lithographic mask structure including mask features corresponding to the specified main features and at least one sub-resolution assist feature (SRAF) structure in a geometrical relationship with a corresponding mask feature for forming, using a lithography process, the unique identifier pattern.

13. The identification structure of claim 12, wherein the formed unique identifier pattern is a one-dimensional barcode-like structure, wherein said specified main features are a series of spaced apart lines, each line of a same pre-determined width and uniform spacing between adjacent lines.

14. The identification structure of claim 13, wherein said at least one SRAF is one or more lines interspersed throughout the series of spaced apart main feature lines.

15. The identification structure of claim 14, wherein the unique identifier pattern comprises a combination of modified main features, wherein the modified main features of said uniquely modified identifier pattern comprises one or more spaced apart lines of varying widths.

16. The identification structure of claim 14, wherein the unique identifier pattern comprises a combination of modified main features, wherein the modified main features of said uniquely modified identifier pattern comprises the spaced apart lines of non-uniform varying spacing between one or more adjacent lines.

17. The identification structure of claim 12, wherein the formed unique identifier pattern is a two-dimensional QR code-like structure.

18. The identification structure of claim 11, wherein the formed unique identifier pattern is a result of a transfer to the surface of a semiconductor wafer using a spatially invariant transformation.

19. The identification structure of claim 11, wherein the formed unique identifier pattern is a result of a transfer to the surface of a semiconductor wafer using a temporally variant transformations of an optical exposure condition, a photoresist layer development condition, or both an optical exposure condition and photoresist layer development condition to vary said uniquely modified identifier pattern as a function of time.

20. The identification structure of claim 11, wherein a semiconductor manufacturing foundry receives the specification of an identifier including the pattern from a customer, the specification specifying the combination of main features that meet a pre-determined manufacturing groundrule.
